(19) United States
(12) Patent Application Publication
(10) Pub. No.: US 2011/0259415 A1
(43) Pub. Date: Oct. 27, 2011

(54) BACKSHEET FOR A PHOTOVOLTAIC MODULE

(75) Inventors: Hsuan-Ping Chen, Kaohsiung County (TW); Hsiang-Yi Yu, Taoyuan County (TW); Wei-Lun Hsiao, Taoyuan County (TW)

(73) Assignee: Du Pont Apollo Limited, Hong Kong (HK)

(21) Appl. No.: 13/093,810

(22) Filed: Apr. 25, 2011

Related U.S. Application Data
(60) Provisional application No. 61/328,186, filed on Apr. 27, 2010.

(51) Int. Cl. H01L 31/0216; H01L 31/0203; B32B 7/02; B32B 13/12; B32B 3/00

(52) U.S. Cl. 136/256; 428/451; 428/332; 428/216; 428/336; 428/212; 136/259

(57) ABSTRACT

Disclosed herein is a backsheet for a photovoltaic module. The backsheet includes a nanocomposite layer, a first polymeric layer and a second polymeric layer. The nanocomposite layer includes a polymeric matrix and a plurality of silicate nanoparticles dispersed therein. The polymeric matrix includes at least one polymer selected from the group consisting of polyester, polyimide, polyethylene terephthalate and nylon. The silicate nanoparticles are made from a silicate clay selected from the group consisting of montmorillonite, sepiolite, fluoromica and vermiculite. The silicate clay is present at a concentration of about 0.5-20% by weight of the nanocomposite layer. The nanocomposite layer is disposed between the first polymeric layer and the second polymeric layer.

### RELATED APPLICATIONS

This application claims priority to U.S. Provisional Application Ser. No. 61/328,186, filed Apr. 27, 2010, which is herein incorporated by reference.

### BACKGROUND

1. Field

The present disclosure relates to a photovoltaic module. More particularly, the present disclosure relates to a backsheet for a photovoltaic module.

2. Description of Related Art

Solar energy has gained much research attention for being a seemingly inexhaustible energy source. For such purpose, solar modules that convert solar energy directly into electrical energy are developed.

In general, the solar module mechanically supports the solar cells, and protects the solar cells against environmental degradation. The solar module generally comprises a rigid and transparent protective front panel such as glass, and a rear panel or sheet, which is typically called a backsheet. The front panel and backsheet encapsulate the solar cell(s) and provide protection from environmental damage.

A known backsheet comprising a weather-resistant layer, a moisture-resistant layer and an insulating layer is disclosed. In general, an aluminum foil is adopted as the moisture-resistant layer. However, the aluminum foil is a conductive material, and thus the insulating requirement of the backsheet may be concerned due to the possibility of electrical leakage through the aluminum foil. Moreover, the aluminum foil is opaque, and thereby the backsheet having the aluminum foil is not suitable for a see-through solar cell.

In view of the above, there exists in this art a need of an improved backsheet, which could resolve the above-mentioned issue.

### SUMMARY

According to one aspect of the present disclosure, a backsheet for a photovoltaic module is disclosed. The backsheet includes a nanocomposite layer, a first polymeric layer and a second polymeric layer. The nanocomposite layer includes a polymeric matrix and a plurality of silicate nanoparticles dispersed therein. The polymeric matrix includes at least one polymer selected from the group consisting of polyester, polyimide, polyethylene terephthalate and nylon. The silicate nanoparticles are made from a silicate clay selected from the group consisting of montmorillonite, sepiolite, fluoromica and vermiculite, and the silicate clay is present at a concentration of about 0.5% to about 20% by weight of the nanocomposite layer. Furthermore, each of the silicate nanoparticles has a multi-layered structure. The multi-layered structure is intercalated with the polymer of the polymeric matrix, or the layers of the multi-layered structure are exfoliated by the polymer of the polymeric matrix. In addition, the first polymeric layer is disposed above the nanocomposite layer. The second polymeric layer is disposed below the nanocomposite layer.

According to another aspect of the present disclosure, a photovoltaic module is disclosed. The photovoltaic module includes a photovoltaic member for converting light into electricity and a backsheet as described above. The photovoltaic member is disposed on the backsheet.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiments, with reference made to the accompanying drawings as follows:

FIG. 1 is a cross-sectional view schematically illustrating a backsheet according to one embodiment of the present disclosure;

FIG. 2 is a cross-sectional view schematically illustrating a backsheet according to another embodiment of the present disclosure;

FIG. 3 is a cross-sectional view schematically illustrating a photovoltaic module according to one embodiment of the present disclosure; and

FIG. 4 is a cross-sectional view schematically illustrating a photovoltaic module according to another embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

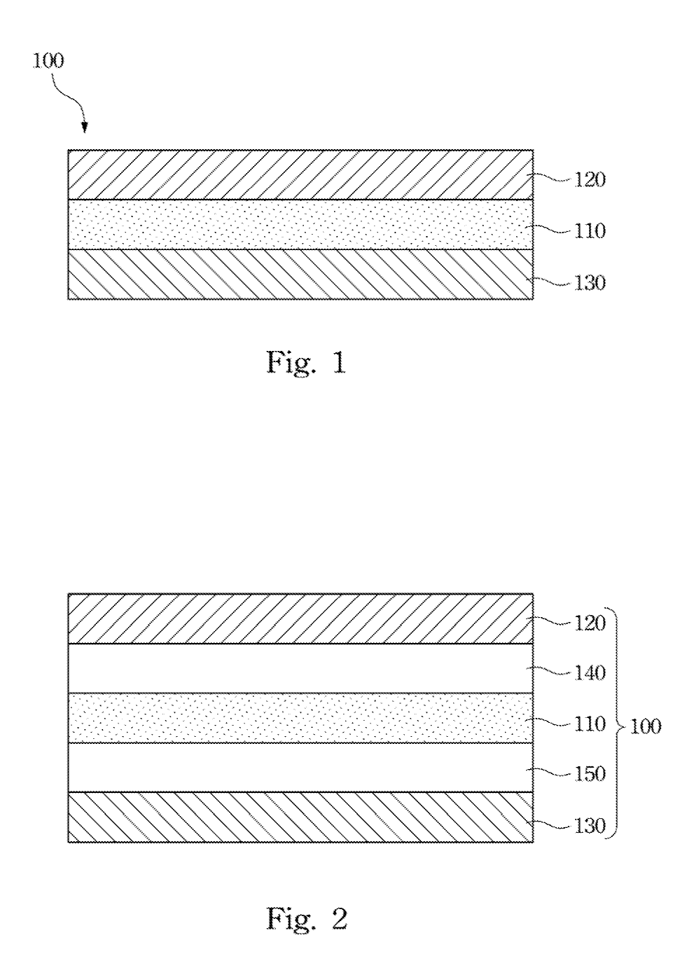

FIG. 1 is a cross-sectional view schematically illustrating a backsheet 100 according to one embodiment of the present disclosure. The backsheet 100 is employed in a photovoltaic module, which converts light into electricity. As depicted in FIG. 1, the backsheet 100 comprises a nanocomposite layer 110, a first polymeric layer 120 and a second polymeric layer 130. The nanocomposite layer 110 is positioned between the first polymeric layer 120 and second polymeric layer 130.

The nanocomposite layer 110 functions as a moisture-resistant layer, and comprises a polymeric matrix and a plurality of silicate nanoparticles homogeneously dispersed in the polymeric matrix. The term “nanoparticles” herein refers to a particle which has at least one dimension in the range of about 0.1 nm to about 900 nm. In one embodiment, the thickness of nanocomposite layer 110 is about 10 μm to about 100 μm.

The polymeric matrix may comprise at least one polymer such as polyester, polyimide, polyethylene terephthalate and nylon. In one example, the polymeric matrix is made of a transparent polymer such as polyethylene terephthalate.

The silicate nanoparticles may comprise at least one silicate clay such as montmorillonite, sepiolite, fluoromica and vermiculite. Each of the silicate nanoparticles has a multi-layered structure. The morphology of the silicate clay existed in the polymeric matrix may be an intercalated structure or an exfoliated structure. Specifically, the multi-layered structure of the silicate nanoparticles is intercalated by the polymer of the polymeric matrix, or the multi-layered structure is exfoliated by the polymer of the polymeric matrix. In some examples, both intercalated and exfoliated structures may simultaneously exist in the polymeric matrix. Typically, the silicate clay exists in a concentration of about 0.5% to about 20% by weight of the nanocomposite layer. More specifically, the concentration of the silicate clay is about 1% to about 10% by weight of the nanocomposite layer. When the concentration of the silicate clay is higher than about 20%, the silicate clay may not be homogeneously dispersed in the polymeric matrix. In particular, a phase separation may occur during the manufacturing process of the nanocomposite layer. On the other hand, when the concentration of the silicate clay is too low, the effect of the moisture resistance is unobvious.

In one embodiment, each layer in the multi-layered structure of the silicate nanoparticle has a length of about 50 nm to about 200 nm, and the thickness of each layer in the multi-layered structure is about 0.5 nm to about 2 nm, more specifically about 1 nm. In this embodiment, the silicate clay may be montmorillonite, for example.

The first polymeric layer 120 is disposed above the nanocomposite layer 110, and provides a function of insulation. A photovoltaic device such as a solar cell may be situated on the first polymeric layer 120. In one embodiment, the first polymeric layer 120 comprises at least one polymer such as polyester, polyimide, polyethylene terephthalate and nylon. In one example, the first polymeric layer 120 may be made of a polymer that is the same as the polymeric matrix. For instance, both the first polymeric layer 120 and polymeric matrix may be made of polyethylene terephthalate, which is a thermoplastic material. In this example, the nanocomposite layer 110 may be directly adhered onto the first polymeric layer 120 by exerting heat to the nanocomposite layer 110. In some examples, the thickness of the first polymeric layer 120 is in the range of about 0.05 mm to about 2 mm.

The second polymeric layer 130 is disposed below the nanocomposite layer 110, and functions as a weather-resistant layer. In one embodiment, the second polymeric layer 130 is made from a transparent polymer such as polyimide or polyethylene terephthalate although it may be made of a fluorinated polymer as well. In some examples, the thickness of the second polymeric layer 130 is in the range of about 0.05 mm to about 2 mm.

In one embodiment, all of the nanocomposite layer 110, first polymeric layer 120 and second polymeric layer 130 are transparent. Accordingly, the backsheet 100 may be employed in a see-through solar cell according to one embodiment of the present disclosure.

Optionally, the backsheet 100 may comprise a first adhesive layer 140 and a second adhesive layer 150, as depicted in FIG. 2. The first adhesive layer 140 is disposed between the first polymeric layer 120 and the nanocomposite layer 110, whereas the second adhesive layer 150 is disposed between the second polymeric layer 130 and the nanocomposite layer 110. The material of the first adhesive layer 140 may be the same as or different from the second adhesive layer 150. The first and/or second adhesive layer(s) may comprise an ethylene-vinyl acetate copolymer (EVA) or polyvinyl butyral (PVB), for example. In some embodiments, both the first and second adhesive layers are about 0.01 mm to about 0.5 mm in thickness.

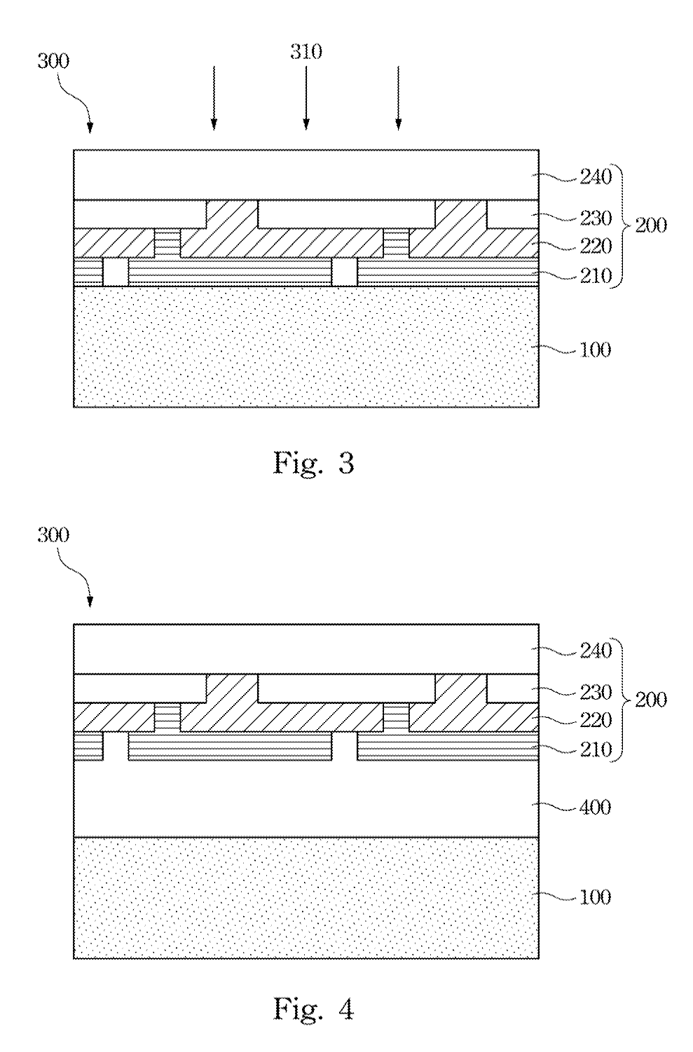

FIG. 3 is a cross-sectional view schematically illustrating a photovoltaic module 300 according to one embodiment of the present disclosure. The photovoltaic module 300 comprises a backsheet 100 and a photovoltaic member 200 for converting light 310 into electricity. In this embodiment, the backsheet 100 is same as those described above. The photovoltaic member 200 may be in contact with the first polymeric layer 120 of the backsheet 100.

As depicted in FIG. 3, the photovoltaic member 200 comprises a back electrode 210, a photoelectric conversion layer 220, a transparent conductive oxide layer 230 and a front transparent substrate 240.

The back electrode 210 is disposed above or on the first polymeric layer of the backsheet 100, and in contact with the photoelectric conversion layer 220. In some examples, the back electrode 210 may be made of silver, aluminum, copper, chromium, nickel or transparent conductive oxide, depending on the needs. The electricity generated by the photoelectric conversion layer 220 may be transmitted to an external loading device through the back electrode 210.

The photoelectric conversion layer 220 for converting light into electricity is sandwiched between the back electrode 210 and the transparent conductive oxide layer 230. It should be noted that in the present disclosure the term “photoelectric conversion layer” comprises all layers that is needed to absorb the light and convert it into electricity. Various thin film semiconductor materials may be employed in the photoelectric conversion layer 220. Suitable materials includes, but is not limited to, amorphous silicon (a-Si:H), polycrystalline silicon, signal crystalline silicon, amorphous silicon carbide (a-SiC), and amorphous silicon-germanium (a-SiGe). In the amorphous silicon embodiment, the photoelectric conversion layer 220 may comprise a p-doped amorphous silicon layer, an intrinsic amorphous silicon layer, and an n-doped amorphous silicon layer (also known as “p-i-n structure”). In this embodiment, the photovoltaic member 200 is a see-through solar cell. Further, a plurality of repetitive p-i-n layers (“pin-pin-pin” or “pin-pin-pin-pin”) may sequentially be formed as well. In other examples, the photoelectric conversion layer 220 may comprise GaAs, CIGS, or CdTe.

The transparent conductive oxide layer 230 is disposed on the photoelectric conversion layer 220. In some examples, the transparent conductive oxide layer 230 may comprise zinc oxide (ZnO), fluorine doped tin dioxide (SnO₂:F), or indium tin oxide (ITO). In some examples, the transparent conductive oxide layer 230 has a textured structure (not shown) on the interface between the transparent conductive oxide layer 230 and the photoelectric conversion layer 220 for trapping light that is transmitted into the photovoltaic member 200.

The front transparent substrate 240 is arranged on the transparent conductive oxide layer 230. In general, the front transparent substrate 240 is disposed on the outmost side of the photovoltaic member 200, and may be made of glass, for example.

In one embodiment, the first polymeric layer of the backsheet 100 is made of a thermoplastic material such as polyethylene terephthalate, on which the photovoltaic member 200 is disposed. The backsheet 100 may be adhered onto the photovoltaic member 200 by exerting heat to the backsheet 100.

In another embodiment, the photovoltaic module 300 may further comprise a sealing layer 400 disposed between the photovoltaic member 200 and the backsheet 100, as depicted in FIG. 4. The photovoltaic member 200 may be adhered to the backsheet 100 by the sealing layer 400. For the purpose of application in a see-through solar cell, the sealing layer 400 may be made from a transparent material such as EVA. However, in other examples, other opaque sealing materials may be employed as well.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A backsheet for a photovoltaic module, comprising:
a nanocomposite layer comprising:
a polymeric matrix comprising at least one polymer selected from the group consisting of polyester, polyimide, polyethylene terephthalate and nylon; and
a plurality of silicate nanoparticles dispersed in the polymeric matrix, each of the silicate nanoparticle having a multi-layered structure, and the multi-layered structure being intercalated with the polymer of the polymeric matrix, or the layers of the multi-layered structure being exfoliated, wherein the silicate nanoparticles are made from a silicate clay selected from the group consisting of montmorillonite, sepiolite, fluoromica and vermiculite;
wherein the silicate clay exists in a concentration of about 0.5 to about 20% by weight of the nanocomposite layer;
a first polymeric layer disposed above the nanocomposite layer; and
a second polymeric layer disposed below the nanocomposite layer.

2. The backsheet according to claim 1, wherein the silicate nanoparticles exists in a concentration of about 1-10% by weight of the nanocomposite layer.

3. The backsheet according to claim 1, wherein each layer of the multi-layered structure has a length of about 50 nm to about 200 nm.

4. The backsheet according to claim 1, wherein each layer of the multi-layered structure has a thickness of about 0.5 nm to about 2 nm.

5. The backsheet according to claim 1, wherein the nanocomposite layer has a thickness of about 10 μm to about 100 μm.

6. The backsheet according to claim 1, wherein the first polymeric layer comprises at least one polymer selected from the group consisting of polyester, polyimide, polyethylene terephthalate and nylon.

7. The backsheet according to claim 6, wherein the first polymeric layer is made of a polymer that is the same as the polymeric matrix.

8. The backsheet according to claim 6, wherein both the first polymeric layer and the polymeric matrix are made of polyethylene terephthalate.

9. The backsheet according to claim 1, wherein the first polymeric layer has a thickness of about 0.01 mm to about 2 mm.

10. The backsheet according to claim 1, wherein the second polymeric layer is made of a fluorinated polymer.

11. The backsheet according to claim 1, wherein the second polymeric layer has a thickness of about 0.01 mm to about 2 mm.

12. The backsheet according to claim 1, further comprising a first adhesive layer disposed between the first polymeric layer and the nanocomposite layer, wherein the first adhesive layer has a thickness of about 0.01 mm to about 0.5 mm.

13. The backsheet according to claim 1, further comprising a second adhesive layer disposed between the second polymeric layer and the nanocomposite layer, wherein the second adhesive layer has a thickness of about 0.01 mm to about 0.5 mm.

14. The backsheet according to claim 1, wherein all the nanocomposite layer, the first polymeric layer and the second polymeric layer are transparent.

15. A photovoltaic module, comprising:
a backsheet set forth in claim 1; and
a photovoltaic member for converting light into electricity and disposed on the first polymeric layer of the backsheet.

16. The photovoltaic module according to claim 15, wherein the photovoltaic member is a see-through solar cell.

17. The photovoltaic module according to claim 16, wherein the see-through solar cell comprises:
a back electrode disposed above the first polymeric layer of the backsheet;
a photoelectric conversion layer disposed on the back electrode;
a transparent conductive oxide layer disposed on the photoelectric conversion layer; and
a front transparent substrate disposed on the transparent conductive oxide layer.

18. The photovoltaic module according to claim 17, wherein the transparent conductive oxide layer comprises at least one material selected from the group consisting of zinc oxide (ZnO), fluorine doped tin dioxide (SnO₂:F), and indium tin oxide (ITO).

19. The photovoltaic module according to claim 17, wherein the transparent conductive oxide layer has a textured structure on the interface between the transparent conductive oxide layer and the photoelectric conversion layer.

20. The photovoltaic module according to claim 17, wherein the photoelectric conversion layer comprises amorphous silicon.
